(19) United States
(12) Patent Application Publication
(10) Pub. No.: US 2026/0013181 A1
(43) Pub. Date: Jan. 8, 2026

(54) SEMICONDUCTOR STRUCTURE WITH ACUTE ANGLE AND FABRICATING METHOD OF THE SAME

(71) Applicant: UNITED MICROELECTRONICS CORP., Hsin-Chu City (TW)

(72) Inventors: Hung-Hsun Shuai, Tainan City (TW); Jyun-Bao Yang, Tainan City (TW); Chih-Jung Chen, Hsinchu County (TW); Ko-Chi Chen, Hsinchu City (TW); Kai-Shun Lin, Kaohsiung City (TW); Shi-Xiong Lin, Yilan County (TW); Po-Wen Su, Kaohsiung City (TW); Lung-En Kuo, Tainan City (TW)

(73) Assignee: UNITED MICROELECTRONICS CORP., Hsin-Chu City (TW)

(21) Appl. No.: 18/795,214

(22) Filed: Aug. 6, 2024

(30) Foreign Application Priority Data
Jul. 2, 2024 (TW) 113124664

(51) Int. Cl. H01L 29/423; H01L 23/525; H01L 29/49; H01L 29/66

(52) U.S. Cl. CPC H10D 30/6892; H01L 23/5252; H10D 30/0411; H10D 64/516; H10D 64/661

(57) ABSTRACT

A semiconductor structure with an acute angle includes a semiconductor substrate. A first isolation layer covers and contacts the semiconductor substrate. A first conductive element is disposed on the first isolation layer. The first conductive element includes a bottom surface and a sidewall. The bottom surface contacts the first isolation layer. An acute angle is formed between the bottom surface and the sidewall, and the acute angle has a tip. A second conductive element is disposed on one side of the first conductive element, wherein the tip pointing toward the second conductive element. An extension surface extends from the bottom surface of the first conductive element, and the extension surface intersects with the second conductive element. A second isolation layer sandwiched between the first conductive element and the second conductive element.

### BACKGROUND OF THE INVENTION

### 1. Field of the Invention

The present invention relates to a semiconductor structure with an acute angle, in particular to a flash with an acute angle and a fabricating method of the same.

### 2. Description of the Prior Art

Semiconductor memory devices are largely divided into volatile semiconductor memory devices and non-volatile semiconductor memory devices. A volatile semiconductor memory device has a high read/write speed, but has a disadvantage in that the stored contents are lost when the external power supply is cut off. On the other hand, the nonvolatile semiconductor memory device retains its contents even when external power supply is interrupted. Therefore, the nonvolatile semiconductor memory device is used to store contents to be preserved regardless of whether power is supplied or not.

With market demand, there has been continuous development in the direction of miniaturizing memory units and increasing memory capacity. Furthermore, flash needs to improve and enhance the performance without increasing additional process costs.

### SUMMARY OF THE INVENTION

In view of this, the present invention provides a flash with an acute angle. In this way, a higher electric field at the tip of the acute angle is formed at the flash, so the operation speed of the flash can be accelerated.

According to a preferred embodiment of the present invention, a semiconductor structure with an acute angle includes a semiconductor substrate. A first isolation layer covers and contacts the semiconductor substrate. A first conductive element is disposed on the first isolation layer, wherein the first conductive element includes a bottom surface and a sidewall, the bottom surface contacts the first isolation layer, an acute angle is formed between the bottom surface and the sidewall, and the acute angle has a tip. A second conductive element is disposed on one side of the first conductive element, wherein the tip points toward the second conductive element, an extension surface extends from the bottom surface of the first conductive element, and the extension surface intersects with the second conductive element. A second isolation layer is sandwiched between the first conductive element and the second conductive element.

According to another preferred embodiment of the present invention, a fabricating method of a semiconductor structure with an acute angle includes providing a semiconductor substrate. Next, a first isolation layer and a first conductive element are sequentially formed to be disposed on the semiconductor substrate, wherein the first isolation layer covers and contacts the semiconductor substrate, the first conductive element includes a bottom surface and a sidewall, the bottom surface contacts the first isolation layer, an acute angle is formed between the bottom surface and the sidewall, and the acute angle has a tip. Then, a second conductive element is formed to be disposed on one side of the first conductive element, wherein the tip points toward the second conductive element, an extension surface extends from the bottom surface of the first conductive element, and the extension surface intersects with the second conductive element. Finally, a second isolation layer is formed to be sandwiched between the first conductive element and the second conductive element.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 depict a fabricating method of a semiconductor structure with an acute angle according to a first preferred embodiment of the present invention, wherein:

FIG. 2 depicts a fabricating stage in continuous of FIG. 1;

FIG. 3 depicts a fabricating stage in continuous of FIG. 2;

FIG. 4 depicts a fabricating stage in continuous of FIG. 3; and

FIG. 5 depicts a fabricating stage in continuous of FIG. 4.

FIG. 6 depicts a fabricating method of a semiconductor structure with an acute angle according to a second preferred embodiment of the present invention.

FIG. 7 to FIG. 9 depict a fabricating method of a semiconductor structure with an acute angle according to a third preferred embodiment of the present invention, wherein:

FIG. 8 depicts a fabricating stage in continuous of FIG. 7; and

FIG. 9 depicts a fabricating stage in continuous of FIG. 8.

FIG. 10 depicts a fabricating method of a semiconductor structure with an acute angle according to a fourth preferred embodiment of the present invention.

FIG. 11 depicts a fabricating method of a semiconductor structure with an acute angle according to a fifth preferred embodiment of the present invention.

FIG. 12 depicts an antifuse according to a sixth preferred embodiment of the present invention.

### DETAILED DESCRIPTION

FIG. 1 to FIG. 5 depict a fabricating method of a semiconductor structure with an acute angle according to a first preferred embodiment of the present invention.

As shown in FIG. 1, a semiconductor substrate 1 is provided. The semiconductor substrate 1 includes a silicon substrate, a germanium substrate, a gallium arsenide substrate, a silicon germanium substrate, an indium phosphide substrate, a gallium nitride substrate, a silicon carbide substrate or a silicon on insulator substrate. Then, an isolation layer 10a, a conductive material layer 12a, an isolation layer 10b, a conductive material layer 12c, an isolation layer 10c, a silicon nitride mask layer 14 and a silicon oxide mask layer 16 are sequentially formed to cover the semiconductor substrate 1. Thereafter, the silicon oxide mask layer 16 and the silicon nitride mask layer 14 are patterned to form an opening 18a.

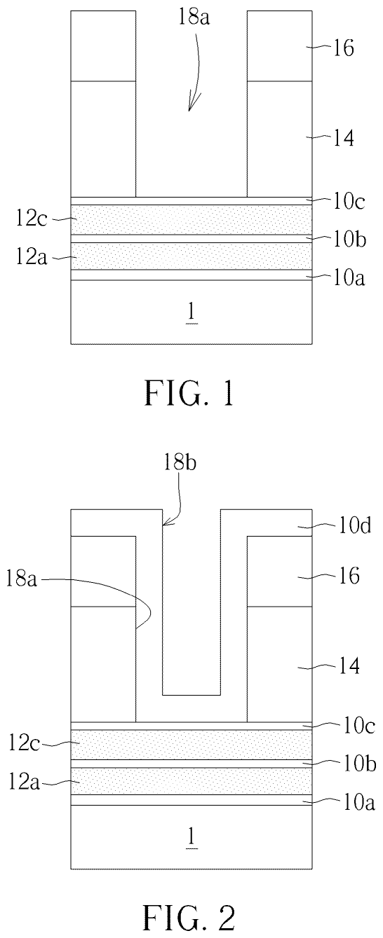

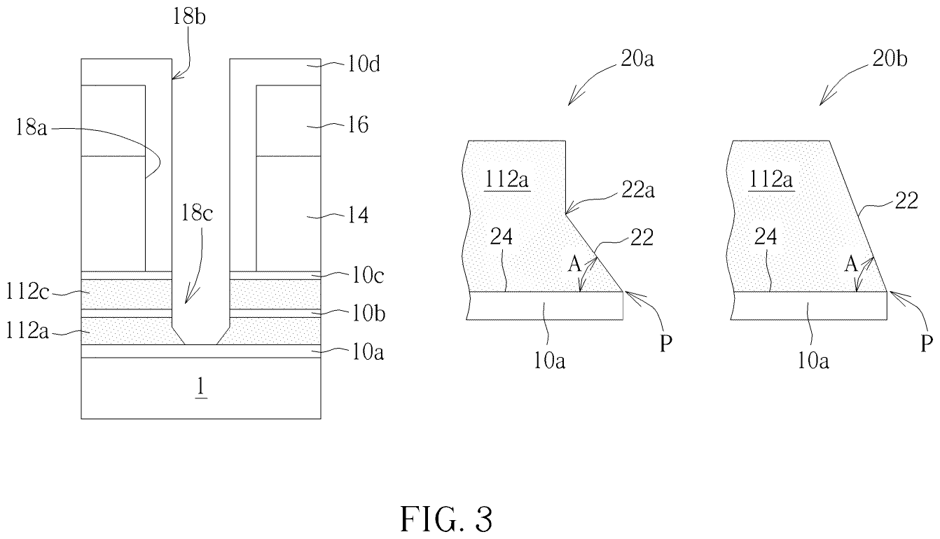

As shown in FIG. 2, an isolation layer 10d is formed to conformally cover the silicon oxide mask layer 16 and the opening 18a. At this time, the isolation layer 10d defines an opening 18b. As shown in FIG. 3, the isolation layer 10c, the conductive material layer 12c, the isolation layer 10b and the conductive material layer 12a are etched to form a trench 18c in the isolation layer 10c, the conductive material layer 12c, the isolation layer 10b and the conductive material layer 12a by using the isolation layer 10d as a mask. The bottom of the trench 18c is the isolation layer 10a. Now, the isolation layer 10c, the conductive material layer 12c, the isolation layer 10b and the conductive material layer 12a are all segmented. The conductive material layer 12a is divided into two first conductive elements 112a. The conductive material layer 12c is divided into two third conductive elements 112c. The structures of the two first conductive elements 112a are mirror symmetry. Taking the first conductive element 112a on the left as an example, as shown in the enlarged view 20a, the first conductive element 112a has a sidewall 22. The sidewall 22 is a V-shaped surface, and the tip 22a of the V-shaped surface is pointed toward the inside of the first conductive element 112a. The angle of the tip 22a is preferably between 135 degrees and 165 degrees. In addition, the first conductive element 112a has a bottom surface 24. The bottom surface 24 contacts the isolation layer 10a. An acute angle A is formed between the bottom surface 24 and the sidewall 22, and the acute angle A has a tip P. According to another preferred embodiment of the present invention, as shown in the enlarged view 20b, the sidewall 22 may be a planar surface. Moreover, please to FIG. 2 and FIG. 3. The trench 18c may be formed by using two types of etching gases. During the etching process, one of the etching gases is used to etch the isolation layer 10c, the conductive material layer 12c, the isolation layer 10b and the conductive material layer 12a, and the other one of the etching gases is used to form a protective layer (not shown) while etching. The protective layer covers isolation layer 10c, the conductive material layer 12c, the isolation layer 10b and the conductive material layer 12a. In this way, the trench 18c can be formed.

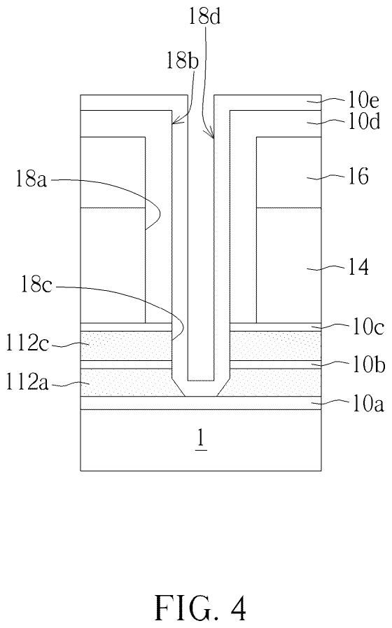

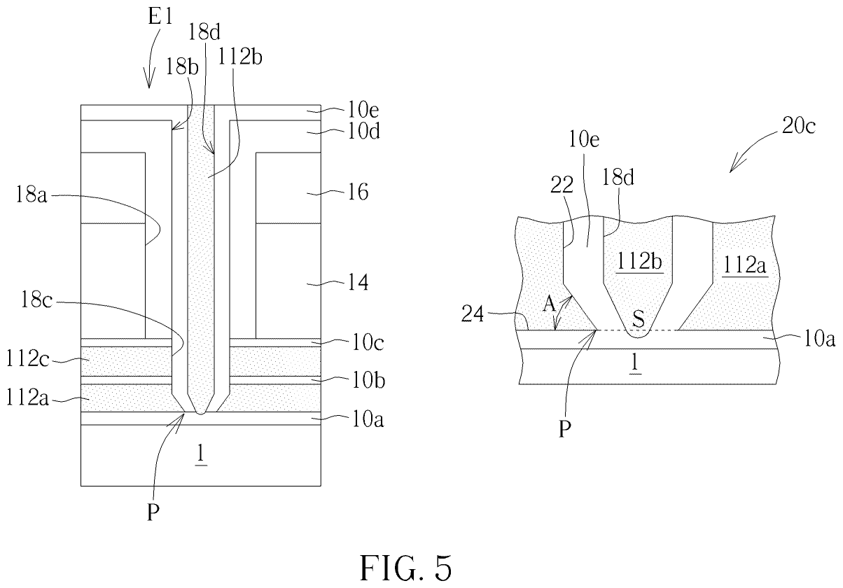

As shown in FIG. 4, an isolation layer 10e is formed to conformally cover the trench 18b and the trench 18c. Now, a trench 18d is defined in the isolation layer 10e. As shown in FIG. 5, the isolation layer 10e and the isolation layer 10a around the tip P are etched so as to thin part of the isolation layer 10e and to extend the trench 18d into the isolation layer 10a. Later, a second conductive element 112b is formed in the trench 18d. As shown in the enlarged view 20c, because the isolation layer 10e around the tip P becomes thinner, the second conductive element 112b can become closer to the tip P. In this way, when the semiconductor structure with an acute angle is turned on, the electric field around the tip P is concentrated, therefore, signals between the first conductive element 112a and the second conductive element 112b can be transmitted more quickly. Now, a flash E1 with an acute angle of the present invention is completed.

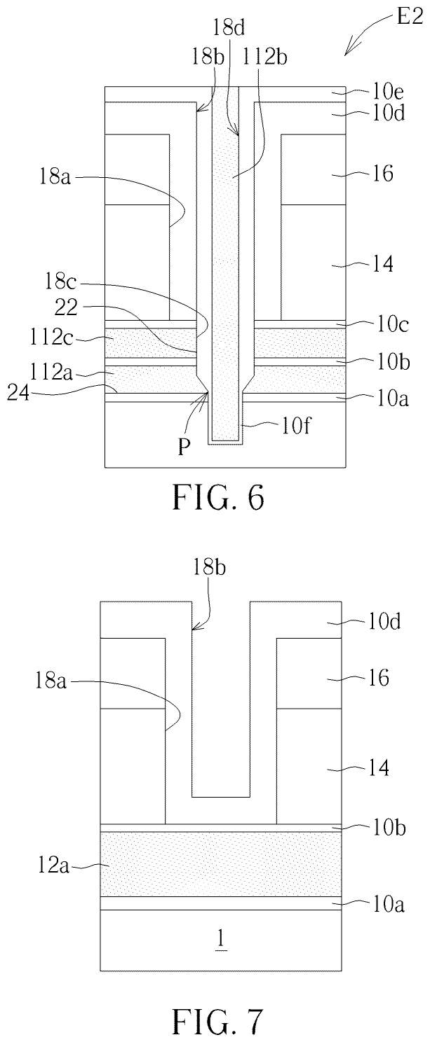

FIG. 6 depicts a fabricating method of a semiconductor structure with an acute angle according to a second preferred embodiment of the present invention.

According to a second preferred embodiment of the present invention, the end of the second conductive element 112b can be embedded in the semiconductor substrate 1. FIG. 6 depicts a fabricating stage in continuous of FIG. 4. As shown in FIG. 6, after forming the isolation layer 10e, the isolation layer 10e at the bottom of the trench 18d is etched and then the isolation layer 10a and the semiconductor substrate 1 are etched to extend the trench 18d into the semiconductor substrate 1. Later, an isolation layer 10f is formed on the sidewall of the trench 18d in the semiconductor substrate 1 by using a thermal oxidation process. Thereafter, the second conductive element 112b in the trench 18d is formed. Now, a flash E2 with an acute angle of the present invention is completed. According to another preferred embodiment of the present invention, the isolation layer 10f can also be formed by using a chemical vapor deposition process. Therefore, the isolation layer 10f not only covers the trench 18d in the semiconductor substrate 1, but also covers the isolation layer 10e. In this way, the isolation layer 10e and the isolation layer 10f are disposed between the second conductive element 112b and the third conductive element 112c, and the isolation layer 10e and the isolation layer 10f are also disposed between the second conductive element 112b and the first conductive element 112a.

FIG. 7 to FIG. 9 depict a fabricating method of a semiconductor structure with an acute angle according to a third preferred embodiment of the present invention, wherein elements which are substantially the same as those in the first preferred embodiment are denoted by the same reference numerals; an accompanying explanation is therefore omitted.

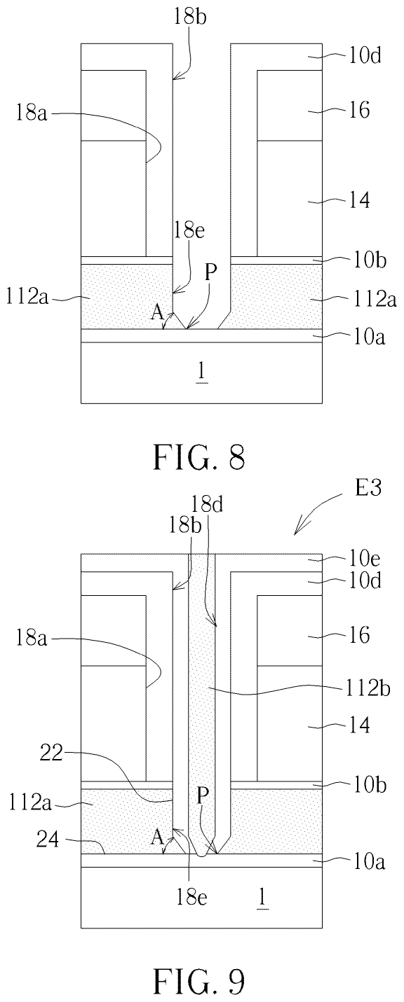

The difference between the third preferred embodiment and the first preferred embodiment is that there is no conductive material layer 12c and isolation layer 10c in the third preferred embodiment, and other elements and fabricating method are the same as those in the first preferred embodiment. As shown in FIG. 7, a semiconductor substrate 1 is provided. Then, an isolation layer 10a, a conductive material layer 12a, an isolation layer 10b, a silicon nitride mask layer 14 and a silicon oxide mask layer 16 are sequentially formed to cover the semiconductor substrate 1. Later, the silicon oxide mask layer 16 and the silicon nitride mask layer 14 are then patterned to form an opening 18a. Next, an isolation layer 10d is formed to conformally cover the silicon oxide mask layer 16 and the opening 18a. At this time, the isolation layer 10d defines an opening 18b. As show in FIG. 8, by using the isolation layer 10d as a mask, the isolation layer 10b and the conductive material layer 12a are etched to form a trench 18e in the isolation layer 10b and the conductive material layer 12a. Now, the acute angle A of the first conductive element 112a also has a tip P. As show in FIG. 9, an isolation layer 10e is formed to conformally cover the trench 18b and the trench 18e to define a trench 18d in the isolation layer 10e. Then, the isolation layer 10e around the tip P is etched. That is, the isolation layer 10e serving as the bottom of the trench 18d is etched. Later, a second conductive element 112b is formed in the trench 18d. Now, a flash E3 with an acute angle of the present invention is completed.

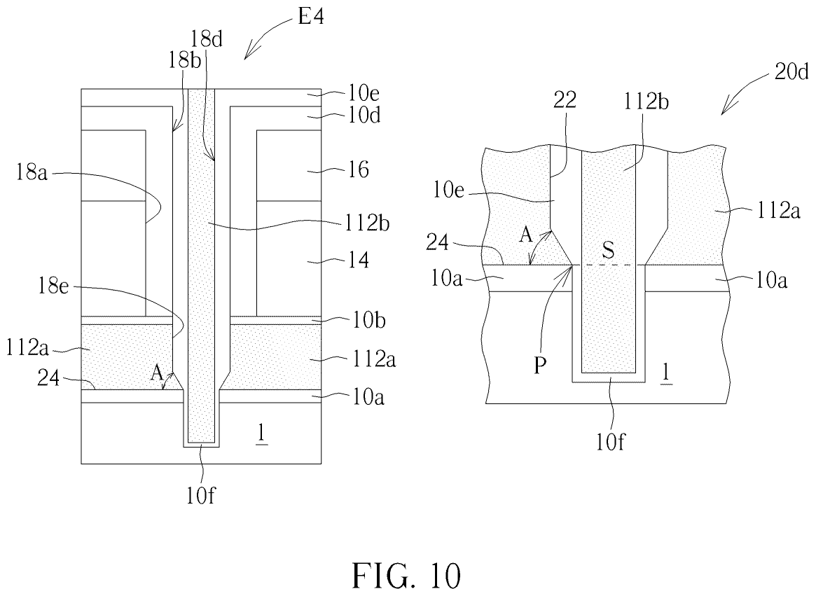

FIG. 10 depicts a fabricating method of a semiconductor structure with an acute angle according to a fourth preferred embodiment of the present invention, wherein elements which are substantially the same as those in the second preferred embodiment are denoted by the same reference numerals; an accompanying explanation is therefore omitted. FIG. 10 depicts a fabricating stage in continuous of FIG. 8. As shown in FIG. 10, an isolation layer 10e is formed to conformally cover the trench 18b and the trench 18e. A trench 18d is defined in the isolation layer 10e. Later, the isolation layer 10e at the bottom of the trench 18d is etched. Next, the isolation layer 10a and the semiconductor substrate 1 are etched to extend the trench 18d into the semiconductor substrate 1. Thereafter, an isolation layer 10f is formed in the trench 18d embedded the semiconductor substrate 1 by using a thermal oxidation process. Finally, a second conductive element 112b is formed in the trench 18d. Now, a flash E4 with an acute angle of the present invention is completed.

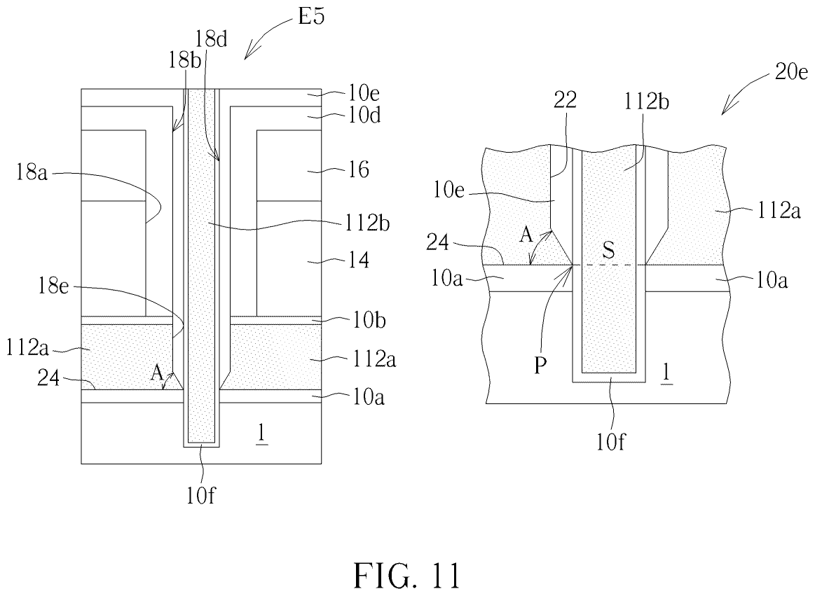

FIG. 11 depicts a fabricating method of a semiconductor structure with an acute angle according to a fifth preferred embodiment of the present invention. The fifth preferred embodiment is a modified embodiment of the fourth preferred embodiment. In the fourth preferred embodiment, a thermal oxidation process is used to form the isolation layer 10f. In the fifth preferred embodiment, a chemical vapor deposition process is used to form the isolation layer 10f. Therefore, in the fifth preferred embodiment, the isolation layer 10f not only covers the trench 18d in the semiconductor substrate 1, but also covers the isolation layer 10e. Except the fabricating method of the isolation layer 10f, other fabricating stages in the fifth preferred embodiment are the same as those in the fourth preferred embodiment. In details, FIG. 11 depicts a fabricating stage in continuous of FIG. 8. As shown in FIG. 11, an isolation layer 10e is formed to conformally cover the trench 18b and the trench 18e to define a trench 18d in the isolation layer 10e. Later, the isolation layer 10e at the bottom of the trench 18d is etched. Next, the isolation layer 10a and the semiconductor substrate 1 are etched to extend the trench 18d into the semiconductor substrate 1. Then, a chemical vapor deposition process is used to conformally form the isolation layer 10f to cover the trench 18d. Finally, a second conductive element 112b is formed in the trench 18d. Now, a semiconductor structure E5 with an acute angle of the present invention is completed.

As shown in FIG. 5, a flash E1 with an acute angle includes a semiconductor substrate 1. An isolation layer 10a covers and contacts the semiconductor substrate 1. A first conductive element 112a is disposed on the isolation layer 10a. A third conductive element 112c is disposed on the first conductive element 112a. A second conductive element 112b is disposed on one side of the first conductive element 112a. The isolation layer 10e is sandwiched between the first conductive element 112a and the second conductive element 112b and between the third conductive element 112c and the second conductive element 112b. The isolation layer 10b is sandwiched between the first conductive element 112a and the third conductive element 112c. Please also refer to the enlarged view 20c in FIG. 5. The first conductive element 112a has a bottom surface 24. The bottom surface 24 contacts the isolation layer 10a. An acute angle A is formed between the bottom surface 24 and the sidewall 22, and the acute angle A has a tip P. The tip P points to the second conductive element 112b, and the acute angle A is preferably between 30 degrees and 60 degrees. An extension surface S (marked by a dotted line) extends from the bottom surface 24 of the first conductive element 112a. The extension surface S is parallel to the top surface of the semiconductor substrate 1. Furthermore, the extension surface S intersects the second conductive element 112b. In this embodiment, the second conductive element 112b is only located on the semiconductor substrate 1 and does not contact the semiconductor substrate 1. In addition, in this embodiment, the first conductive element 112a is a floating gate, the second conductive element 112b is an erase gate, and the third conductive element 112c is a control gate. The first conductive element 112a includes polysilicon, the second conductive element 112b includes polysilicon or metal, and the third conductive element 112c includes polysilicon.

As shown in FIG. 6, the differences between the flash E1 with an acute angle and the flash E2 with an acute angle is that: in the flash E2 with an acute angle, the end of the second conductive element 112b is embedded in the semiconductor substrate 1. Furthermore, an isolation layer 10f is disposed between the second conductive element 112b and the semiconductor substrate 1. Other elements are the same as those in the flash E1 with an acute angle, therefore please refer to the description in FIG. 5 and the relevant descriptions are omitted here.

As shown in FIG. 10, a flash E4 with an acute angle includes a semiconductor substrate 1. An isolation layer 10a covers and contacts the semiconductor substrate 1. A first conductive element 112a is disposed on the isolation layer 10a. Please also refer to the enlarged view 20d in FIG. 10. The first conductive element 112a has a bottom surface 24 and a sidewall 22. The bottom surface 24 contacts the isolation layer 10a. An acute angle A is formed between the bottom surface 24 and the sidewall 22, and the acute angle A has a tip P. The acute angle A is preferably between 30 degrees and 60 degrees. A second conductive element 112b is disposed on one side of the first conductive element 112a. The tip P points toward the second conductive element 112b. An extension surface S (marked by a dotted line) extends from the bottom surface 24 of the first conductive element 112a. The extension surface S is parallel to the bottom surface 24. Furthermore, the extension surface S intersects the second conductive element 112b. An isolation layer 10e is sandwiched between the first conductive element 112a and the second conductive element 112b. The first conductive element 112a includes polysilicon, the second conductive element 112b includes polysilicon or metal, the first conductive element 112a is a floating gate, and the second conductive element 112b is a control gate.

As shown in FIG. 10 and FIG. 11, the differences between the flash E4 with an acute angle and the flash E5 with an acute angle is that: in the flash E5 with an acute angle, the isolation layer 10f not only covers the trench 18d in the semiconductor substrate 1, but also covers the isolation layer 10e so as to make the isolation layer 10e and the isolation layer 10f disposed between the second conductive element 112b and the first conductive element 112a. However, the end of the second conductive element 112b embedded in the substrate 1 only contacts the isolation layer 10f. The isolation layer 10e is not embedded in the substrate 1. In the enlarged view 20e in FIG. 11, similarly to the enlarged view 20d, there is also an acute angle A between the bottom surface 24 and the sidewall 22, and the acute angle A has a tip P. The acute angle A is preferably between 30 degrees and 60 degrees. Other elements are the same as those in the flash E4 with an acute angle, therefore please refer to the description in FIG. 10 and the relevant descriptions are omitted here.

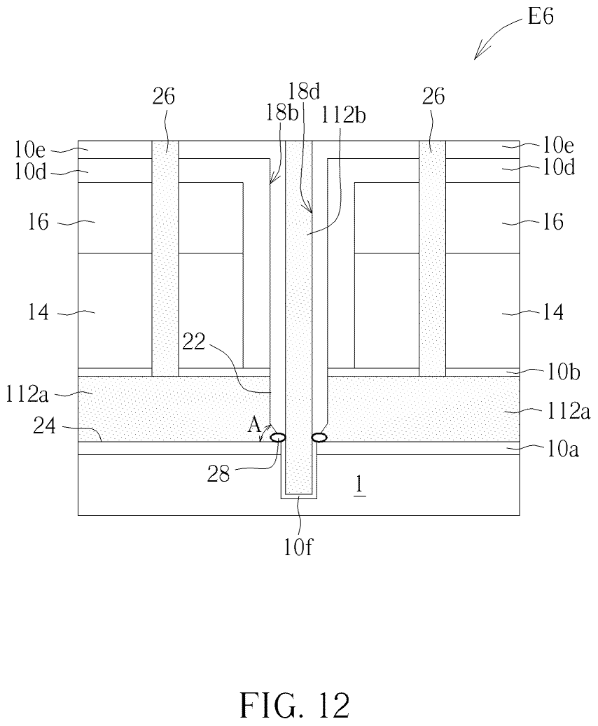

FIG. 12 depicts an antifuse according to a sixth preferred embodiment of the present invention. As shown in FIG. 10, the structure of the flash E4 in FIG. 10 can also be used as antifuse. As shown in FIG. 12, the structure of antifuse E6 is similar to that of flash E4 with an acute angle, except one conductive plug 26 is disposed on the first conductive element 112a to contact the first conductive element 112a. When enough voltage is applied to the second conductive element 112b and the conductive plug 26, the isolation layer 10e and the isolation layer 10f are collapsed so as to form a conductive block 28 between the first conductive element 112a and the second conductive element 112b as a current path. In this way, the antifuse E6 is programmed. Other elements in FIG. 12 are the same as those in FIG. 10, therefore please refer to the description in FIG. 10 and the relevant descriptions are omitted here.

In addition, the material of the isolation layers 10a/10b/10c/10d/10e/10f in all the preferred embodiments described in this invention respectively includes silicon oxide, silicon nitride, silicon nitride carbide, silicon oxynitride or silicon oxycarbonitride. The first conductive element 112a, the second conductive element 112b, and the third conductive element 112c respectively include conductive materials such as polysilicon, copper, tungsten, aluminum, titanium, alloys or other conductive materials.

In the present invention, the corner of the first conductive element is specially etched into an acute angle. Because the electric field at the tip of the acute angle is high, a tunneling effect is formed quickly between the first conductive element and the second conductive element, which can improve the operation speed of the flash memory.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure with an acute angle, comprising:
a semiconductor substrate;
a first isolation layer covering and contacting the semiconductor substrate;
a first conductive element disposed on the first isolation layer, wherein the first conductive element comprises a bottom surface and a sidewall, the bottom surface contacts the first isolation layer, an acute angle is formed between the bottom surface and the sidewall, and the acute angle has a tip;
a second conductive element disposed on one side of the first conductive element, wherein the tip points toward the second conductive element, an extension surface extends from the bottom surface of the first conductive element, and the extension surface intersects with the second conductive element; and
a second isolation layer sandwiched between the first conductive element and the second conductive element.

2. The semiconductor structure with an acute angle of claim 1, wherein the first conductive element comprises polysilicon, a conductive plug is disposed on a top surface of the first conductive element, the second conductive element comprises metal or alloy, and the semiconductor structure with an acute angle is an antifuse.

3. The semiconductor structure with an acute angle of claim 1, wherein the first conductive element comprises polysilicon, the second conductive element comprises polysilicon or metal, the first conductive element is a floating gate, the second conductive element is a control gate, and the semiconductor structure with an acute angle is a flash.

4. The semiconductor structure with an acute angle of claim 1, further comprising:
a third conductive element disposed on the first conductive element, wherein the second isolation layer is sandwiched between the third conductive element and the second conductive element; and
a third isolation layer sandwiched between the first conductive element and the third conductive element.

5. The semiconductor structure with an acute angle of claim 4, wherein the first conductive element comprises polysilicon, the second conductive element comprises polysilicon or metal, the third conductive element comprises polysilicon, the first conductive element is a floating gate, the second conductive element is an erase gate, and the third conductive element is a control gate, and the semiconductor structure with an acute angle is a flash.

6. The semiconductor structure with an acute angle of claim 1, wherein the second conductive element is disposed only on the semiconductor substrate.

7. The semiconductor structure with an acute angle of claim 1, wherein an end of the second conductive element is embedded in the semiconductor substrate.

8. The semiconductor structure with an acute angle of claim 7, further comprising a fourth isolation layer covering and contacting the second isolation layer, the fourth isolation layer is embedded in the semiconductor substrate and contacts the end of the second conductive element, wherein the fourth isolation layer and the second isolation layer are disposed between the first conductive element and the second conductive element, the end of the second conductive element does not contact the second isolation layer.

9. The semiconductor structure with an acute angle of claim 1, wherein the sidewall is a planar surface.

10. The semiconductor structure with an acute angle of claim 1, wherein the sidewall is a V-shaped surface, and a first tip of the V-shaped surface faces toward the first conductive element.

11. A fabricating method of a semiconductor structure with an acute angle, comprising:
providing a semiconductor substrate;
sequentially forming a first isolation layer and a first conductive element disposed on the semiconductor substrate, wherein the first isolation layer covers and contacts the semiconductor substrate, the first conductive element comprises a bottom surface and a sidewall, the bottom surface contacts the first isolation layer, an acute angle is formed between the bottom surface and the sidewall, and the acute angle has a tip;
forming a second conductive element disposed on one side of the first conductive element, wherein the tip points toward the second conductive element, an extension surface extends from the bottom surface of the first conductive element, and the extension surface intersects with the second conductive element; and
forming a second isolation layer sandwiched between the first conductive element and the second conductive element.

12. The fabricating method of a semiconductor structure with an acute angle of claim 11, wherein the first conductive element comprises polysilicon, a conductive plug is disposed on a top surface of the first conductive element, the second conductive element comprises metal or alloy, and the semiconductor structure with an acute angle is an antifuse.

13. The fabricating method of a semiconductor structure with an acute angle of claim 11, wherein the first conductive element comprises polysilicon, the second conductive element comprises polysilicon or metal, the first conductive element is a floating gate, the second conductive element is a control gate, and the semiconductor structure with an acute angle is a flash.

14. The fabricating method of a semiconductor structure with an acute angle of claim 11, further comprising:
forming a third conductive element disposed on the first conductive element, wherein the second isolation layer is sandwiched between the third conductive element and the second conductive element; and
forming a third isolation layer sandwiched between the first conductive element and the third conductive element.

15. The fabricating method of a semiconductor structure with an acute angle of claim 14, wherein the first conductive element comprises polysilicon, the second conductive element comprises polysilicon or metal, the third conductive element comprises polysilicon, the first conductive element is a floating gate, the second conductive element is an erase gate, and the third conductive element is a control gate, and the semiconductor structure with an acute angle is a flash.

16. The fabricating method of a semiconductor structure with an acute angle of claim 11, wherein the second conductive element is disposed only on the semiconductor substrate.

17. The fabricating method of a semiconductor structure with an acute angle of claim 11, wherein an end of the second conductive element is embedded in the semiconductor substrate.

18. The fabricating method of a semiconductor structure with an acute angle of claim 17, further comprising:
forming a fourth isolation layer by using a chemical vapor deposition, wherein the fourth isolation layer covers and contacts the second isolation layer, the fourth isolation layer is embedded in the semiconductor substrate and contacts the end of the second conductive element.

19. The fabricating method of a semiconductor structure with an acute angle of claim 11, wherein the sidewall is a planar surface.

20. The fabricating method of a semiconductor structure with an acute angle of claim 11, wherein the sidewall is a V-shaped surface, and the V-shaped surface shrinks toward an inside of the first conductive element.
